(19) United States
(12) Patent Application Publication
(10) Pub. No.: US 2024/0345906 A1
(43) Pub. Date: Oct. 17, 2024

(54) STORAGE DEVICE PREDICTING FAILURE USING MACHINE LEARNING AND METHOD OF OPERATING THE SAME

(71) Applicant: Samsung Electronics Co., Ltd., Suwon-si (KR)

(72) Inventors: Yongwong KWON, Suwon-si (KR); Ho-Jin AHN, Suwon-si (KR); Dohyun CHOI, Suwon-si (KR); Sungtae LEE, Suwon-si (KR)

(73) Assignee: Samsung Electronics Co., Ltd., Suwon-si (KR)

(21) Appl. No.: 18/479,739

(22) Filed: Oct. 2, 2023

(30) Foreign Application Priority Data
Apr. 14, 2023 (KR) 10-2023-0049197

(51) Int. Cl. G06F 11/07; G06F 11/34

(52) U.S. Cl. CPC G06F 11/0772; G06F 11/0778; G06F 11/0784; G06F 11/3452

(57) ABSTRACT

A failure prediction method of predicting a failure of a storage device includes: identifying at least a portion of telemetry information, stored in a memory, as risk data based on a predetermined first criterion; inputting first data of a first attribute, among the risk data, to a machine learning model; obtaining a first anomaly score output from the machine learning model; detecting whether an anomaly is present in the first attribute, based on whether the first anomaly score satisfies a predetermined second criterion; transmitting an alert, associated with the first attribute, to a host when an anomaly is detected for the first attribute, among the risk data; and receiving feedback, corresponding to the alert, from the host. The machine learning model may receive the risk data to learn a pattern of data, and may output an anomaly score of the received data based on the learned pattern of the data.

### CROSS-REFERENCE TO RELATED APPLICATION(S)

This application claims benefit of priority to Korean Patent Application No. 10-2023-0049197, filed on Apr. 14, 2023, in the Korean Intellectual Property Office, the disclosures of which are incorporated herein by reference in its entirety.

### BACKGROUND

The present disclosure relates to a storage device.

The storage device may include, e.g., a semiconductor memory device implemented using a semiconductor such as silicon (Si), germanium (Ge), gallium arsenide (GaAs), indium phosphide (InP), or the like. Semiconductor memory devices are classified into volatile memory devices and nonvolatile memory devices.

For example, flash memory, an example of nonvolatile memory, may retain stored data thereof even when a power supply thereof is interrupted. Recently, storage devices including said flash memory, such as a solid-state drive (SSD) or a memory card, have been widely used, and are useful in storing or moving a large amount of data.

In such storage devices, a state of such a storage device may be checked, and telemetry may be periodically monitored to take measures in response to a failure. When a failure is detected, a follow-up measure is taken against the defected failure.

However, such measures are limited to follow-up measures after occurrence of a failure in a storage device, which may result in consumption of time or resources associated with recovery and/or reconstruction of corrupted data, as well as data corruption and/or permanent data loss due to said failure.

### SUMMARY

Example embodiments provide a storage device predicting occurrence of a failure using a machine learning model and taking a preemptive measure.

According to at least one example embodiment, a failure prediction method of predicting a failure of a storage device includes: identifying risk data from at least a portion of telemetry information, stored in a memory, based on a first criterion; inputting first data of a first attribute, from among the risk data, to a machine learning model; obtaining a first anomaly score output from the machine learning model; detecting whether an anomaly is present in the first attribute, based on a determination of whether the first anomaly score satisfies a second criterion; transmitting an alert, associated with the first attribute, to a host in response to the anomaly being detected; and controlling an operation of the storage device in response to receiving feedback, corresponding to the alert, from the host. The machine learning model may be configured to be trained on the risk data, to learn a pattern of data from the risk data, and may output anomaly scores based on the learned pattern of the data.

According to at least one example embodiment, a storage device includes: a nonvolatile memory; and a controller comprising a memory configured to store telemetry information on the storage device. The controller may be configured to: identify risk data from at least a portion of telemetry information, stored in at least one of the memory or the nonvolatile memory, based on a first criterion; input first data of a first attribute, from among the risk data, to a machine learning model; obtain a first anomaly score output from the machine learning model; detect whether an anomaly is present in the first attribute, based on whether the first anomaly score satisfies a predetermined second criterion; transmit an alert, associated with the first attribute, to a host in response to the anomaly being detected; and control an operation of the storage device in response to receiving feedback. The machine learning model may be configured to be trained on the risk data, to learn a pattern of data from the risk data, and to output anomaly scores based on the learned pattern of the data.

According to at least one example embodiment, a storage device includes a controller and a nonvolatile memory. The controller may include: a memory configured to store telemetry information on the storage device; and processing circuitry configured to store risk data identified; store a debug dump based on detection of an anomaly; and to identify risk data at least a portion of telemetry information, stored in the memory, based on a first criterion; detect whether an anomaly is present in at least a portion of attributes, among the stored risk data, through a machine learning model trained using the identified risk data; transmit an alert, associated with an attribute in which the anomaly is detected, to a host in response to an anomaly being detected; and control an operation of the storage device in response to receiving feedback, corresponding to the alert, from the host. The machine learning model may be configured to learn a pattern of received data, and to output anomaly scores based on the learned pattern of the data.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a block diagram illustrating a storage system according to at least one example embodiment.

FIG. 2 is a block diagram illustrating an example of a controller of FIG. 1.

FIG. 3 is a flowchart illustrating an example of an operation of a storage device of FIG. 1.

FIG. 4 is a flowchart illustrating an example of operation S10 of FIG. 3 in which a controller identifies risk data.

FIG. 5A is a flowchart illustrating an example of operation S20 in which the controller detects an anomaly using risk data.

FIG. 5B is a flowchart illustrating an example of operation S20 in which the controller detects an anomaly using variance data.

FIG. 6 is a flowchart illustrating an example of operation S30 of FIG. 3 in which debug features are enabled as a controller detects an anomaly.

FIG. 7 is a flowchart illustrating an operation of controlling a storage device based on feedback received from a host according to at least one example embodiment.

FIG. 8 is a block diagram illustrating a storage system according to at least one example embodiment.

FIG. 9 is a diagram illustrating an example of risk data stored by a telemetry module of FIG. 8.

FIG. 10 is a flowchart illustrating an example of an operation in which the telemetry module of FIG. 8 stores risk data depending on a period.

FIG. 11 is a diagram illustrating a storage system further including a debug module according to at least one example embodiment.

FIG. 12 is a diagram illustrating an example of a debug dump stored by the debug module.

FIG. 13 is a flowchart illustrating an operation of storing a debug dump, corresponding to enabled debug features, when a failure occurs in a storage device.

FIG. 14 is a diagram illustrating a storage system further including a telemetry module and a debug module according to at least one example embodiment.

### DETAILED DESCRIPTION

Hereinafter, example embodiments will be described with reference to the accompanying drawings.

In the following description, any of the elements and/or functional blocks disclosed, including those including “unit”, “ . . . er/or,” “module”, etc., may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

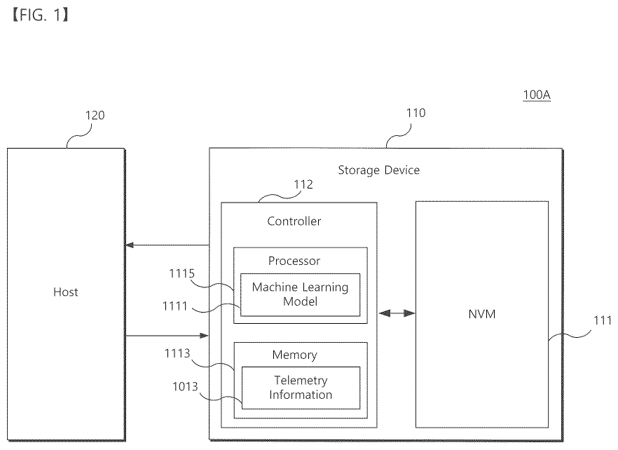

FIG. 1 is a block diagram illustrating a storage system 100A according to at least one example embodiment.

The storage system 100A includes a storage device 110 and a host 120. The storage device 110 is configured to detect an anomaly, in which a failure is likely to occur, using a machine learning model. The anomaly may be, for example, a symptom of an occurrence of a failure and/or a prognostic symptom of the failure. Accordingly, the storage device 110 may be configured to take a preemptive measure before the failure occurs.

The storage system 100A is implemented as and/or implemented in, for example, a personal computer (PC), a data server, a network-coupled storage, an Internet of Things (IoT) device, a portable electronic device, or the like. For example, the portable electronic device may be a laptop computer, a mobile phone, a smartphone, a tablet PC, a personal digital assistant (PDA.), an enterprise digital assistant (EDA), a digital still camera, a digital video camera, an audio device, a portable multimedia player (PMP), a personal navigation device (PND), an MPEG-1 audio layer 3 (MP3) player, a handheld game console, an electronic book (e-hook), or a wearable device.

The host 120 is configured to receive an alert associated with an anomaly from the storage device 110 and to transmit a feedback signal corresponding to the received alert to the storage device 110. Also, the host 120 may transmit a signal, requesting additional information (e.g., associated with to a detected anomaly), to the storage device 110. As described above, a communication between the host 120 and the storage device 110 may be referred to as a bidirectional communication.

The host 120 may be, e.g., a processor. For example, according to at least one example embodiment, the host 120 may be an application processor (AP). Additionally, according to at least one example embodiment, the host 120 may be implemented as a system-on-a-chip (SoC).

The storage device 110 is configured to store data transmitted from the host 120, and to transmit the stored data to the host 120.

According to at least one example embodiment, the storage device 110 may be an internal memory embedded in an electronic device. For example, the storage device 110 may be at least one of an SSD, an embedded universal flash storage (UFS) memory device, an embedded multimedia card (eMMC), or like. According to another example embodiment, the storage device 110 may be an external memory, removable from an electronic device. For example, the storage device 110 may be a UFS memory card, compact flash (CF), secure digital (SD), micro secure digital (Micro-SD), mini secure digital (Mini-SD), extreme digital (xD), a memory stick, or the like. However, the storage device 110 is not limited to the above examples.

The storage device 110 according to at least one example embodiment may include a controller 112 and a nonvolatile memory (NVM) 111.

The nonvolatile memory 111 may include a memory cell array (MCA). The memory cell array MCA may include a plurality of flash memory cells. The plurality of flash memory cells may be, for example, NAND flash memory cells. However, example embodiments are not limited thereto, and the memory cells may be memory cells such as resistive RAM (ReRAM) cells, phase change RAM (PRAM) cells, magnetic RAM (MRAM) cells, or the like. In at least some embodiments, the storage device 110 includes at least one telemeter (not illustrated) configured to collect in situ information and to transfer the in situ information to the controller 112 as telemetry information 1113. In at least one embodiment, the telemeter may measure, e.g., the temperature, speed, voltage drops, etc., of the nonvolatile memory 111 while in operation. Additionally, in at least some embodiments, the controller 112 may be configured to collect telemetry information 1113 by monitoring the performance of read and/or write operations performed by the nonvolatile memory 111. For example, the controller 112 may be configured to monitor for media-related information, input/output (I/O) related information, link information, and/or the like.

The controller 112 includes a processor 1115 and memory 1113 and is configured to control the overall operation of the nonvolatile memory 111. For example, the controller 112 may read data stored in the nonvolatile memory 111, and may write data in the nonvolatile memory 111. The processor 1115 may be configured to implement a machine learning model 1111.

In at least one example embodiment, the controller 112 is configured to detect an anomaly of the storage device 110 using the machine learning model 1111, and to provide an alert associated with the anomaly to the host 120. For example, the controller 112 may identify at least a portion of telemetry information 1013 as risk data based on a first predetermined criterion, and may determine whether an anomaly is present in some attributes of the risk data, using the machine learning model 1111. In at least one embodiment, the telemetry information 1013 may include at least one of media-related information, input/output (I/O) related information, link information, environment information, and/or the like. When an anomaly is detected, the controller 112 may transmit the alert, associated with detected anomaly, to the host 120.

The memory 1113 may store the telemetry information 1013. For example, among a plurality of attributes of the storage devices 110, an attribute to be monitored may be preset, and the memory 1113 may store the telemetry information 1013 including data corresponding to the preset attribute. For example, the telemetry information 1013 may include at least one of self-monitoring analysis and reporting technology (SMART) information and/or extended SMART attribute information defined by, e.g., nonvolatile memory express (NVMe), serial advanced technology attachment (SATA), parallel ATA (PATA), small computer system interface (SCSI), serial attached SCSI (SAS), enhanced small disk interface (ESDI), and/or integrated drive electronics (IDE) standards, but the example embodiments are not limited thereto. The telemetry information 1013 may also be referred to as, for example, telemetry attribute information and/or telemetry superset information.

The processor 1115 may include processing circuitry, such as a central processing unit or a microprocessor, and is configured to control the overall operation of the controller 112.

Also, the processor 1115 may include the machine learning model 1111. In FIG. 1, the machine learning model 1111 is illustrated as being implemented within the processor 1115, but the example embodiments are not limited thereto. As another example, the machine learning model 1111 may be implemented as a separate module connected to the processor 1115.

According to at least one example embodiment, the processor 1115 may identify at least a portion of the telemetry information 1013, stored in the memory 1113, as risk data based on the first criterion.

For example, the processor 1115 may identify an attribute and data satisfying the first criterion, among the telemetry information 1013 stored in the memory 1113, as risk data. In these cases, the first criterion may be enable a determination of whether a data value of an attribute included in the telemetry information 1013 is greater than a predetermined first reference value.

For example, wherein the attribute to be monitored includes the temperature of the storage device 110 and the telemetry information 1013 includes temperature data of the storage device 110 when the temperature of the storage device 110 is greater than the predetermined first reference value, the processor 1115 may manage the temperature data of the storage device 110 as a candidate attribute and may identify temperature data as risk data.

Furthermore, the processor 1115 may detect an anomaly, in which a failure is likely to occur in the storage device 110, using the risk data and the machine learning model 1111.

For example, the processor 1115 may input risk data or variance data, generated from the risk data, to the machine learning model 1111. Then, the processor 1115 may determine whether an anomaly is present in some attributes of the risk data, based on an output of the machine learning model 1111.

In these cases, the machine learning model 1111 may be obtained by receiving data (for example, risk data) associated with the attributes of the storage device 110 and learning a pattern from the received data. Accordingly, the machine learning model 1111 may output an anomaly score of the input risk data based on the learned pattern.

According to at least one example embodiment, the processor 1115 may input data of a specific attribute, among the risk data, to the machine learning model 1111. Then, the processor 1115 may determine whether an anomaly is present in the corresponding attribute, based on whether a first anomaly score, output by the machine learning model 1111, satisfies a predetermined second criterion. In these cases, the second criterion may enable a determination of whether the first anomaly score, output from the machine learning model 1111, is greater than a predetermined second reference value.

For example, the risk data may be data on temperature, and the machine learning model 1111 may receive the data on temperature and may output an anomaly score for an input temperature. In these cases, when the anomaly score for the temperature (or change in temperature) is greater than the predetermined second reference value, the processor 1115 may determine that an anomaly has occurred.

Also, the processor 1115 may input variance data (generated from the risk data) to the machine learning model 1111. Then, the processor 1115 may determine whether an anomaly has occurred, based on whether a second anomaly score, output by the machine learning model 1111, satisfies a predetermined third criterion. In these cases, the third criterion may enable a determination of whether the second anomaly score is greater than a predetermined third reference value.

For example, the risk data may be data on temperature and/or temperature changes, and the machine learning model 1111 may receive data on temperature variance and may output an anomaly score for the input temperature variance. In these cases, when the anomaly score for the temperature variance is greater than the predetermined third reference value, the processor 1115 may determine that an anomaly has occurred.

Also, the processor 1115 may determine whether an anomaly has occurred, based on whether data of a specific attribute, among the risk data, satisfies a predetermined fourth criterion. In these cases, the fourth criterion enables a determination of whether the data of the specific attribute, among the risk data, exceeds a predetermined fourth reference value.

For example, when temperature data, among the risk data, exceeds a predetermined fourth reference value, the processor 1115 may determine that an anomaly has occurred in a temperature attribute. In these cases, the fourth reference value may be set to a higher temperature than the first reference value.

Furthermore, when detecting an anomaly, the processor 1115 may transmit an alert associated with the detected anomaly to the host 120. In these cases, the alert transmitted to the host 120 may include at least one of a causal factor of the detected anomaly, an anomaly-detected attribute, or data associated with the anomaly.

The processor 1115 may receive feedback, corresponding to the received alert, from the host 120. In these cases, the feedback received from the host 120 may include a control signal for the storage device 110. Accordingly, the processor 1115 may control the operation of the storage device 110 based on the control signal included in the received feedback.

As described above, the storage device 110 is configured to detect an anomaly, in which a defect is likely to occur, using the machine learning model 1111. Thus, the storage system 100A according to the present disclosure may take a preemptive measure before a failure occurs in the storage device 110.

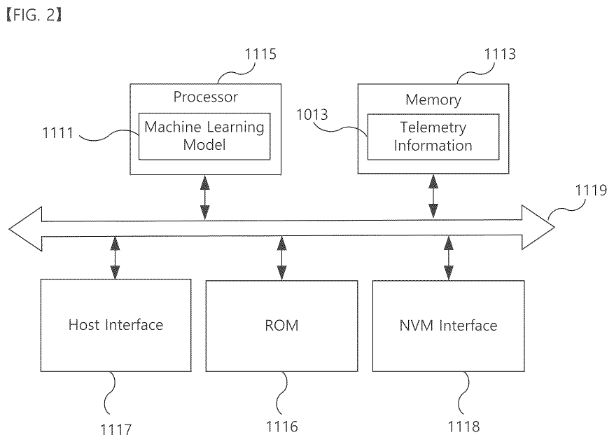

FIG. 2 is a block diagram illustrating an example of the controller 112 of FIG. 1.

Referring to FIG. 2, the controller 112 may include a memory 1113, a processor 1115, a read-only memory (ROM) 1116, a host interface 1117, and a nonvolatile memory (NVM) interface 1118, which are configured to communicate with each other through a bus 1119.

The memory 1113 is configured to operate under the control of the processor 1115, and may be used as a working memory or a buffer memory. For example, the memory 1113 may be implemented as a dynamic random access memory (DRAM). However, this is merely an example, and the memory 1113 may include a nonvolatile memory (such as a PRAM, a flash memory, and/or the like) and/or a volatile memory (such as a DRAM, a static random access memory (SRAM), and/or the like).

The ROM 1116 may store code data used for the initial booting of the storage device 110.

The host interface 1117 is configured provide interfacing between the host 120 and the controller 112, and may provide interfacing based on, for example, universal serial bus (USB), multimedia card (MMC), peripheral component interconnection (PCI) express (PIC-E), advanced technology attachment (ATA), serial ATA (SATA), parallel ATA (PATA), small computer system interface (SCSI), serial attached SCSI (SAS), enhanced small disk interface (ESDI), integrated drive electronics (IDE), or NVM express (NVMe).

The nonvolatile memory interface 115 is configured to provide interfacing between the controller 112 and the nonvolatile memory 111.

The machine learning model 1111 is configured to implemented based on anomaly detection methodologies. For example, in at least one embodiment, the machine learning model 1111 may learn a normal pattern of a data set based on a decision tree, and may apply an unsupervised learning model (such as an isolation forest model) to measure anomaly scores based on the degree of isolation of input data and normal patterns.

The machine learning model 1111 according to at least one embodiment may be an anomaly detection model based on a deep neural network, such as an auto encoder, from a traditional machine learning methodology such as 1-Class SVM, Gaussian Mixture Model (GMM), k-nearest neighbor (k-NN), PCA, and/or the like.

However, the type and configuration of the machine learning model 1111 according to the present disclosure is not limited to the above-described examples, and the machine learning model 111 may be referred to as various types of models for outputting anomaly scores from input data associated with attributes of the storage device 110.

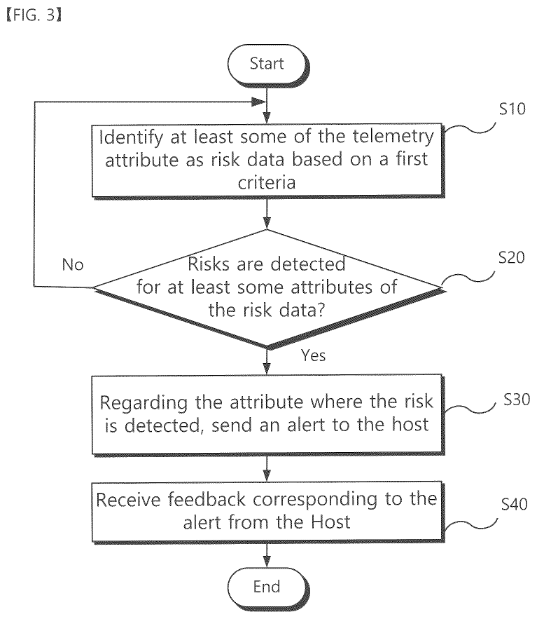

FIG. 3 is a flowchart illustrating an example of an operation of the storage device 110 of FIG. 1.

Referring to FIGS. 1 to 3 together, the controller 112 is configured to detect an anomaly, in which a failure is likely to occur in the storage device 110, using the machine learning model 1111. Furthermore, the controller 112 is configured to transmit an alert, associated with the detected anomaly, to the host 120. Then, the controller 112 may receive feedback based on the transmitted alert.

In operation S10, the controller 112 identifies at least a portion of the telemetry information 1013 as risk data based on a first predetermined criterion. In these cases, the first criterion may enable a determination of whether a data value of an attribute, included in the telemetry information 1013, is greater than a predetermined first reference value. The attribute may be associated with attributes or statuses of the storage device 110.

In at least one example embodiment, in operation S10, when data of some attributes, among the telemetry information 1013, exceeds a reference value corresponding to each of the attributes, the controller 112 may identify the attributes as risk data.

For example, in operation S10, when first data of a first attribute, among the telemetry information 1013, exceeds a first reference value corresponding to the first attribute, the controller 112 may identify the first data as risk data.

In operation S20, the controller 112 may detect whether an anomaly is present in some attributes, among the identified risk data, using the machine learning model 1111.

For example, in operation S20, the controller 112 inputs the risk data, identified through operation S10, to the learned machine learning model 1111, and determines whether an anomaly is present in at least a portion of attributes of the risk data, based on an output of the machine learning model 1111.

In these cases, the machine learning model 1111 receives the identified risk data to identify and/or learn a pattern of data and to learn how to output anomaly scores of the input data.

In operation S30, the controller 112 transmits an alert, associated with an anomaly-detected attribute, to the host 120 when an anomaly is detected in at least a portion of attributes of the risk data.

In these cases, the alert transmitted to the host 120 may include data associated with an anomaly-detected attribute. For example, the alert transmitted to the host 120 may include at least one of an anomaly-detected attribute, data of the corresponding attribute, and a causal factor of the detected anomaly.

In at least some embodiments, the controller 112 may be configured to transmit an alert to the host 120 through an asynchronous event request (AER) command.

In operation S40, the controller 112 receives feedback, corresponding to the alert transmitted to the host 120, from the host 120.

In these cases, the feedback may include a control signal including a measure for the detected anomaly and/or a signal requesting additional information on the detected anomaly. However, the signal included in the feedback is not limited to the above example, and may include various signals or data received from the host 120 through the host interface 1117.

Furthermore, in operation S40, the controller 112 controls the storage device 110, based on the feedback received from the host 120, to prevent a failure from occurring in the storage device 110. Additionally, in at least one embodiment, operations S10 through S40 may repeat until anomalies are no longer identified and/or detected. In at least one embodiment, after operation S40, the controller 112 may return to operation S101 (discussed below).

As described above, the storage device 110 according to at least one example embodiment may detect an anomaly, in which a failure is likely to occur, using the machine learning model 1111. Thus, the storage system 100A according to the present disclosure may take a preemptive measure before a failure occurs in the storage device 110.

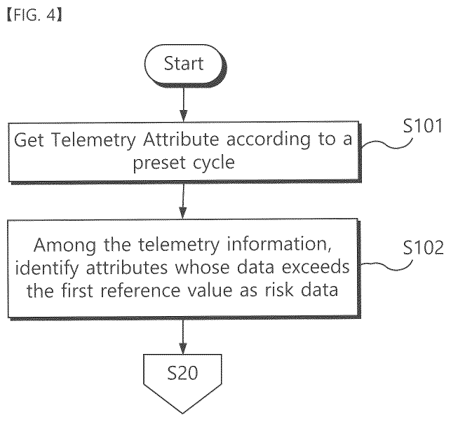

FIG. 4 is a flowchart illustrating an example of operation S10 of FIG. 3 in which the controller identifies risk data.

Referring to FIG. 4, the controller 112 according to at least one example embodiment may identify at least a portion of the telemetry information 1013 as risk data, based on predetermined periods and criteria.

In operation S101, the controller 112 according to at least one example embodiment may obtain the telemetry information 1013 based on a predetermined period.

For example, the controller 112 monitors the storage device based on the predetermined period to obtain the telemetry information 1013. In these cases, the telemetry information 1013 obtained based on the predetermined period may be temporarily stored in the memory 1113. However, this is merely an example, and the telemetry information 1013 obtained based on the predetermined period may be stored in the nonvolatile memory 111.

In at least one example embodiment, the telemetry information 1013 of the storage device 110 may be stored in the memory 1113 or the nonvolatile memory 111 in real time or based on a first period, and the controller 112 may monitor the memory 1113 based on a second period to obtain the telemetry information 1013. In these cases, the first period and the second period may be different from each other.

The telemetry information 1013 may include at least one of media-related information, input/output (I/O) related information, link information, and environment information.

For example, the media-related information may include a write or read media unit, a program/erase failure count, a bad block count, a wear-leveling count, and an uncorrectable by error correction code (UECC) of the storage device 110, and/or the like.

The I/O related information may include at least one of a read count (for example, read I/O), a write count (for example, write I/O), a maximum writable number of the nonvolatile memory (for example, lifetime NAND write), and a maximum readable number of the nonvolatile memory (for example, lifetime NAND read), which are requested from a host.

The link information may include at least one of an end-to-end (E2E) error count, a cyclic redundancy check (CRC) error count, a peripheral component interconnect express (PCIe) correctable error, and a physical layer (PHY) error count of the storage device 110.

The environment information may include at least one of a current temperature, a maximum temperature, a highest temperature for lifelong, a lowest temperature for lifelong, and a dynamic temperature throttle (DTT), and/or the like of the storage device 110.

However, the attributes and data included in the telemetry information 1013 are not limited to the above examples, and may refer to various types of attributes (or states) associated with the storage device 110.

In operation S102, the controller 112 identifies whether at least a portion of attributes, among the telemetry information 1013, is risk data based on a first criterion. In these cases, the first criterion may enable a determination of whether data of some attributes, among the telemetry information 1013, exceeds a predetermined first reference value.

For example, in operation S102, when the data of some attributes, among the telemetry information 1013, exceeds the predetermined first reference value, the controller 112 may identify the corresponding attributes and data as risk data.

In at least one example, the controller 112 may identify a first attribute and first data as risk data in response to the fact that the first data of the first attribute, among the telemetry information 1013, is greater than a predetermined first reference value. For example, the controller 112 may identify a temperature attribute and data as risk data in response to the fact that the data of the temperature attribute, among the telemetry information 1013, exceeds a predetermined temperature value.

Furthermore, the controller 112 may be configured to control the learning of the machine learning model 1111 such that the machine learning model 1111 is trained to output anomaly scores of input data using the identified risk data.

For example, the risk data identified by the controller 112 may be understood as learning data for learning how the machine learning model 1111 outputs anomaly scores of input data.

As described above, the storage device 110 may select data, satisfying a predetermined criterion, from among the telemetry information 1013 to train the machine learning model 1111. Thus, the storage device 110 may save resources required to train the machine learning model 1111.

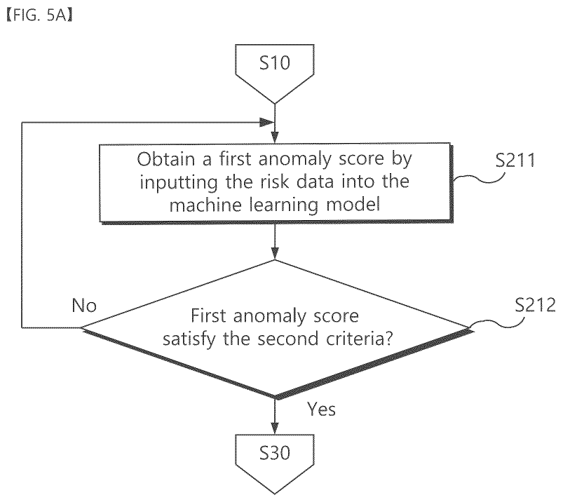

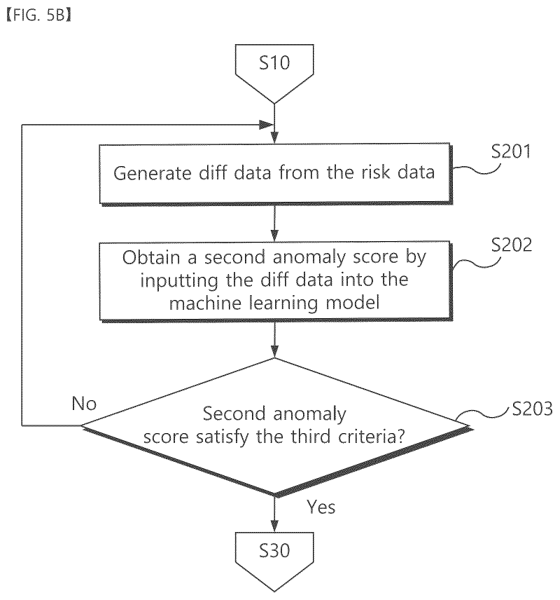

FIG. 5A is a flowchart illustrating an example of operation S20 in which the controller detects an anomaly using risk data, and FIG. 5B is a flowchart illustrating an example of operation S20 in which the controller detects an anomaly using variance data.

Referring to FIGS. 5A and 5B together, the controller 112 according to at least one example embodiment may determine whether an anomaly is present in an attribute included in risk data, using the machine learning model 1111.

As an example, the controller 112 may input risk data or variance data, generated from the risk data, to the machine learning model 1111. Then, the controller 112 may determine whether an anomaly is present in an attribute included in the risk data, based on an output of the machine learning model 1111.

Referring to FIG. 5A, the controller 112 according to at least one example embodiment may determine whether an anomaly is present in some attributes of the risk data, using the risk data.

In operation S211, the controller 112 inputs the risk data to the machine learning model 1111. For example, in operation S211, the controller 112 may input data of at least a portion of attributes, among the risk data, to the machine learning model 1111.

In operation S211, the controller 112 obtains a first anomaly score from the machine learning model 1111.

For example, the controller 112 may input temperature data, among the risk data, to the machine learning model 1111 and may obtain an anomaly score for the input temperature data.

In at least some embodiments, the machine learning model 1111 may also learn (or be trained) to output an anomaly score of the input risk data based on a difference from a previously learned data pattern. For example, the risk data may be understood as learning data used to train the machine learning model 1111.

In operation S212, the controller 112 determines whether the first anomaly score, obtained from the machine learning model 1111, satisfies a second criterion.

For example, in operation S212, the controller 112 may determine that an anomaly has occurred in a specific attribute, in response to the fact that the first anomaly score obtained by inputting data of the specific attribute (among the risk data) to the machine learning model 111 satisfies the second criterion.

In these cases, the second criterion may enable a determination of whether the first anomaly score obtained by inputting data on a specific attribute, among the risk data, to the machine learning model 1111 is greater than a predetermined second reference value.

For example, the controller 112 may determine that an anomaly has occurred in the temperature attribute, in response to the fact that the first anomaly score obtained by inputting the temperature data, among the risk data, to the machine learning model 1111 is greater than the second reference value.

According to at least one embodiment, the controller 112 may determine whether an anomaly is present, based on whether data of a specific attribute, among the risk data, satisfies a predetermined fourth criterion.

For example, when data of some attributes, among the risk data, exceeds a predetermined fourth reference value, the controller 112 may determine that an anomaly has occurred in a corresponding attribute.

For example, when the temperature data (among the risk data) exceeds a predetermined reference temperature value for the temperature attribute, the controller 112 may determine that an anomaly has occurred in the temperature attribute.

As described above, the storage device 110 according to at least one example embodiment may determine whether an anomaly is present, based on a value of the risk data or an anomaly score obtained by inputting the risk data to the machine learning model 1111.

Thus, the storage device 110 may increase accuracy of determining whether an anomaly is present.

Additionally (or alternatively), referring to FIG. 5B, the controller 112 according to at least one example embodiment may determine whether an anomaly is present in an attribute included in the risk data, using variance data generated from the risk data.

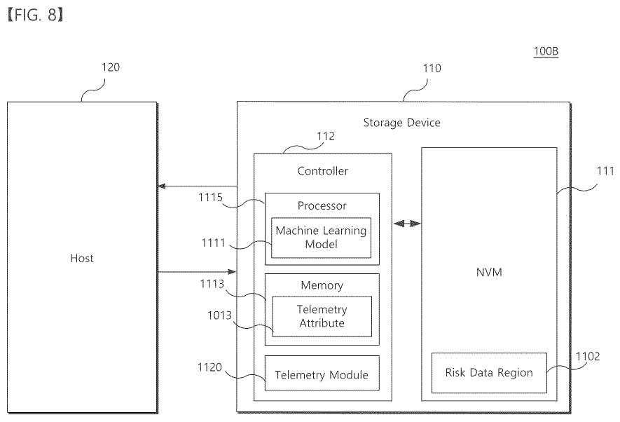

In operation S201, the controller 112 may generate variation data from risk data stored by, e.g., a telemetry module (1120 of FIG. 8).

For example, in operation S201, the controller 112 may generate variance data including a variance of data depending on time points with respect to some attributes of the risk data.

For example, when the risk data is data on a temperature, the controller 112 may generate variance data including a temperature variance compared with a temperature at a previous time point. As another example, when the risk data is data on workload, the controller 112 may generate variance data including a variance of workload compared with a workload at a different time point.

In operation S202, the controller 112 may input the variation data to the machine learning model 1111 to obtain a second anomaly score from the machine learning model 1111. For example, the controller 112 may input data on the temperature variance to the machine learning model 1111 to obtain an anomaly score for the input temperature variance.

In these cases, the machine learning model 1111 may be configured to (e.g., through learning) how to output an anomaly score of the input variation data based on a difference from a previously learned normal data pattern. For example, the variation data generated from the risk data may be understood as training data used to train the machine learning model 1111.

In operation S203, the controller 112 may determine whether the second anomaly score obtained through the machine learning model 1111 satisfies the third criterion. Furthermore, the controller 112 may determine that an anomaly has occurred, in response to the fact that the second anomaly satisfies the third criterion.

The third criterion may enable a determination of whether the second anomaly score obtained through the machine learning model 1111 is greater than the predetermined third reference value.

The controller 112 may determine that an anomaly has occurred in the first attribute, in response to the fact that the second anomaly score obtained by inputting the variation data on the first attribute to the machine learning model 1111 satisfies the third criterion.

For example, the controller 112 may input variance data on the temperature attribute to the machine learning model 1111 to determine whether the second anomaly score is greater than the third reference value.

As described above, the storage device 110 according to at least one example embodiment may determine whether an anomaly is present, based on an anomaly score obtained by inputting the variation data to the machine learning model 1111.

Thus, the storage device 110 may increase accuracy of determining whether an anomaly is present and to secure timeliness in determining whether an anomaly is present such that preemptive measure can be applied before the occurrence of a failure.

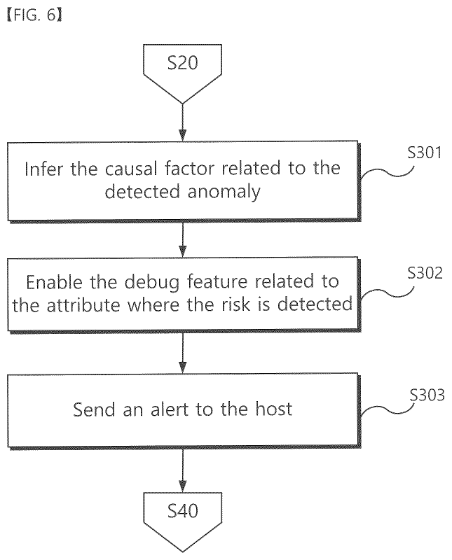

FIG. 6 is a flowchart illustrating an example of operation S30 of FIG. 3 in which a debug feature is enabled as the controller detects an anomaly.

Referring to FIG. 6, the controller 112 according to at least one example embodiment may enable a debug feature, associated with a detected anomaly, in response to the fact that an anomaly is detected in the risk data.

In operation S301, the controller 112 may infer a causal factor of a detected anomaly in response to the fact that an anomaly is detected in some attributes of the risk data.

For example, in operation S301, the controller 112 according to at least one example embodiment may infer a causal factor of the detected anomaly using the machine learning model 1111. For example, when an anomaly is detected in some attribute, the machine learning model 1111 may be set to learn to infer a cause of the anomaly based on data of a corresponding attribute or an anomaly score measured from the data.

According to at least one embodiment, in operation S301, the controller 112 may infer a causal factor of the detected anomaly based on a predetermined cause of the anomaly for each attribute included in the risk data.

In operation S302, the controller 112 enables debug features associated with an attribute in which an anomaly is detected.

For example, in operation S302, the controller 112 may enable a debug feature associated with the inferred causal factor for the detected anomaly. For example, the controller 112 may enable a debug feature associated with a cell spread in which an anomaly has been detected.

In operation S303, the controller 112 may transmit an alert, including at least one of the causal factor or data associated with the debug feature, to the host in response to inference of the causal factor of the detected anomaly.

In at least one embodiment, operation S303 in which the controller 112 transmits an alert to the host 120 and operation S302 in which the controller 112 enables debug features may be simultaneously performed, or may be continuously performed regardless of the order thereof.

As described above, the storage device 110 according to the present disclosure may enable debug features corresponding to an attribute in which an anomaly has been detected. Thus, when a failure occurs in the storage device 110, the storage system 100A may store a debug dump corresponding to the enabled debug feature to be available in failure analysis or performance improvement.

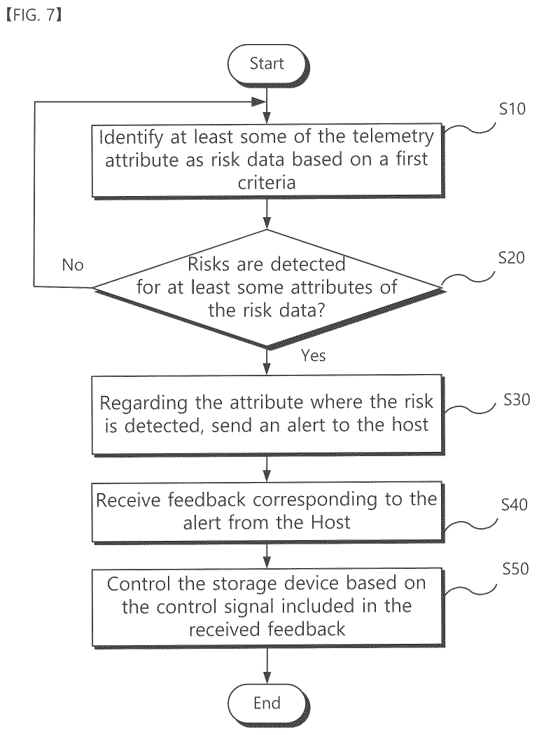

FIG. 7 is a flowchart illustrating an operation of controlling a storage device based on feedback received from a host according to at least one example embodiment.

FIG. 7 represents an operation in which the controller 112 controls the storage device 110, as an example different from the example of FIG. 3. The same or substantially similar operations to those described above are denoted by the same reference numerals, and redundant descriptions will be omitted.

Referring to FIG. 7, in operation S50, the controller 112 controls the storage device 110 based on feedback received from the host 120.

In operation S50, the controller 112 may control an operation of the storage device 110 based on the control signal, included in the feedback received from the host 120, to prevent a failure from occurring in the storage device 110.

For example, the controller 112 may receive the feedback from host 120 in response to an alert transmitted to the host 120 when an anomaly has been determined among the risk data. The controller 112 may control an operation of the storage device 110 such that the data of the temperature attribute is adjusted within a predetermined range based on a control signal included in the feedback.

As described above, the storage device 110 may take a preemptive measure to prevent a failure from occurring in the storage device 110 based on the fact that an anomaly is detected before a failure occurs. Thus, a failure can be preemptively prevented, even in cases wherein an eminent failure may occur before human intervention can be applied, and the storage device 110 may prevent data loss caused by occurrence of failure and may significantly reduce resources required for data recovery.

According to at least one embodiment, the controller 112 may train the machine learning model 1111 based on the feedback received from the host 120.

For example, the controller 112 may detect an anomaly for a specific attribute through the machine learning model 1111 to transmit an alert to the host 120. However, when the host 120 determines that a failure caused by the anomaly is unlikely to occur, the controller 112 may input the feedback, received from the host 120, to the machine learning model 1111. Thus, the machine learning model 1111 may be trained to include even data, in which an anomaly has been detected, in a normal pattern.

According to at least one example embodiment, the machine learning model 1111 may learn to output a modulated criterion for at least one criterion, among criteria for selecting risk data and/or detecting an anomaly.

For example, the machine learning model 1111 may train to output a first modulation criterion, modulated for a first criterion for identifying the risk data from the telemetry information 1013, based on the feedback received from host 120.

Also, the machine learning model 1111 may train to output a second modulation criterion, modulated for a second criterion for determining whether an anomaly is present from data of a specific attribute, among the risk data, based on the feedback received from the host 120.

Also, the machine learning model 1111 may train to output a third modulation criterion, modulated for a third criterion for determining whether an anomaly is present from an anomaly score output by the machine learning model 1111, based on the feedback received from the host 120.

For example, the storage device 110 may control the training of the machine learning model 1111 to modulate a value of criterion for determining whether an anomaly is present, in addition to determining an anomaly score. Thus, the storage device 110 may improve accuracy of determining whether an anomaly is present, using the machine learning model 1111.

According to at least one embodiment, the feedback received from the host 120 may include a signal requesting additional information on a detected anomaly.

Accordingly, the controller 112 may transmit additional information, associated with the detected anomaly, to the host 120 in response to a request for additional information included in the feedback received from the host 120.

In these cases, the additional information transmitted to the host 120 by the controller 112 may include at least one of a data value of an anomaly-detected attribute, variance data, a causal factor of the anomaly, a debug dump associated with the detected anomaly, and/or the like. However, data included in the additional information is not limited to the above example, and may be referred to as various types of data associated with the detected anomaly.

Thus, the host 120 may transmit additional feedback, including a control signal generated based on the additional information, to the controller 112.

Then, the controller 112 may receive additional feedback from the host 120, including a control signal having high accuracy. Furthermore, the controller 112 may control the storage device 110 based on the received control signal. Thus, accuracy of controlling the storage device 110 may be increased.

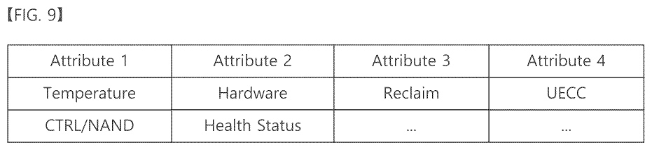

FIG. 8 is a block diagram illustrating a storage system 100B according to at least one example embodiment, and FIG. 9 is a diagram illustrating an example of risk data stored by a telemetry module 1120 of FIG. 8.

Regarding to FIG. 8, the same reference numerals denote the same or substantially similar elements described above, as compared with the storage system 100A of FIG. 1, and redundant descriptions will be omitted. The controller 112 of FIG. 8 may further include a telemetry module 1120 configured to store identified risk data.

Referring to FIGS. 8 and 9 together, the telemetry module 1120 is configured to store attributes and data identified as risk data, among telemetry information 1013, and to manage the stored attributes and data.

For example, when the risk data is identified from the telemetry information 1013, the controller 112 may transmit the identified risk data and attributes thereof to the telemetry module 1120. The telemetry module 1120 may store the attributes identified as risk data and corresponding risk data in a risk data area 1102 of the nonvolatile memory 111.

In at least one example embodiment, the telemetry module 1120 is configured to accumulate attributes identified as the risk data and the corresponding risk data and to store the accumulated attributes and risk data in the risk data area 1102 of the nonvolatile memory 111. The accumulated risk data may be used to generate variance data to be provided to the machine learning model 1111. Only the risk data, rather than the entire telemetry information 1013, may be accumulated and stored, so that a storage space used to accumulate and store the risk data may be reduced.

Referring to FIG. 9, attributes included in the risk data may include at least one of temperature, hardware, reclaim, uncorrectable by error correction code (UECC), health status, and/or the like. However, the attributes included in the risk data are not limited to the above examples, and may include more or less data, such as various types of data associated with attributes (or statuses) of the storage device 110.

In these cases, the risk data may be stored in a table format by the telemetry module 1120. However, the type and/or the table format in which the risk data is stored is not limited thereto.

In FIGS. 8 and 9, the risk data has been described as being accumulated and stored in the nonvolatile memory 111. However, these are merely an example, and the example embodiments are not limited thereto. For example, the risk data may be accumulated and stored in the memory 1113 of the controller 112. In these cases, the risk data stored in the memory 1113 may be flushed to the nonvolatile memory 111 according to a predetermined period. As another example, the controller 112 may further include a main memory implemented as a nonvolatile memory, and the risk data may be stored in the nonvolatile memory in the controller 112.

An area, used to implement the storage device 110, may be reduced through to the above-described configuration. For example, the storage device 110 may satisfy an area, required for a mobile device, through the above-described configuration.

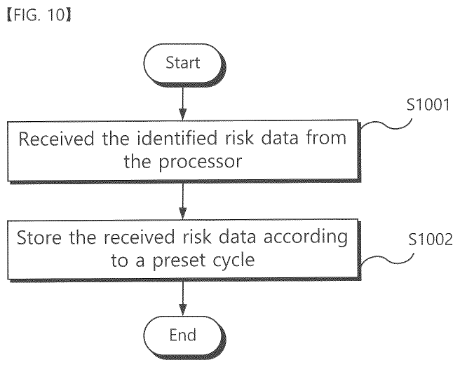

FIG. 10 is a flowchart illustrating an example of an operation in which the telemetry module of FIG. 8 stores risk data according to a period.

In operation S1001, the telemetry module 1120 receives identified risk data from the processor 1115.

For example, the telemetry module 1120 may receive the identified risk data from the processor 1115 in response to the fact that the processor 1115 identifies the risk data and/or the telemetry module 1120 may receive the identified risk data from the processor 1115 according to a predetermined period.

In operation S1002, the telemetry module 1120 may store the risk data, received from the processor 1115, in the nonvolatile memory 111 according to a predetermined period.

In at least one embodiment, in operation S1002, the telemetry module 1120 stores the identified risk data in the memory 1113 according to a predetermined period.

For example, an element storing the identified risk data is not limited to the nonvolatile memory 111 or the memory 1113.

The telemetry module 1120 according to at least one example embodiment may store and manage the risk data received from the processor 1115 according to a predetermined period.

Thus, the storage device 110 according to the present disclosure may separately store and manage attributes in which an anomaly is likely to occur.

As described above, the storage device 110 may accumulate and store only risk data, rather than the entire telemetry information 1013, so that a storage space required to accumulate and store the risk data may be reduced.

Accordingly, an area used to implement the storage device 110 may be reduced. For example, the storage device 110 may satisfy an area, required for a mobile device, through the above-described configuration.

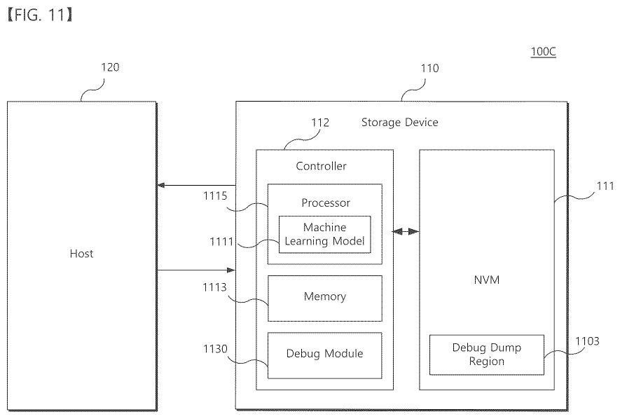

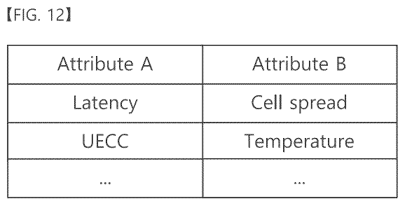

FIG. 11 is a diagram illustrating a storage system 100C further including a debug module according to at least one example embodiment, and FIG. 12 is a diagram illustrating an example of a debug dump stored by the debug module.

Regarding to FIG. 11, the same reference numerals denote the same or substantially similar elements described above, as compared with the storage system 100A of FIG. 1, and redundant descriptions will be omitted. The controller 112 of FIG. 11 may further include a debug module 1130 storing a debug dump.

Referring to FIGS. 11 and 12 together, the debug module 1130 is configured to store a debug dump corresponding to previously enabled debug features in response to the fact that a failure occurs in the storage device 110.

In at least one example embodiment, the debug module 1130 is configured to accumulate debug data corresponding to the enabled debug features and to store the debug data in a debug dump area 1103 of a nonvolatile memory 111 as a debug dump. Thus, only debug data corresponding to the enabled debug features associated with a failure, rather than the entire debug data, may be accumulated and stored, so that a storage space required to accumulate and store the debug data may be reduced.

For example, referring to FIG. 12, a debug dump stored at the time of occurrence of a failure may include at least one of cell spread, latency, UECC, and temperature. In these cases, the debug dump may be stored in the nonvolatile memory 111 in a table format. However, the type and/or storage format of data (or debug log) included in the debug dump are not limited to the above example.

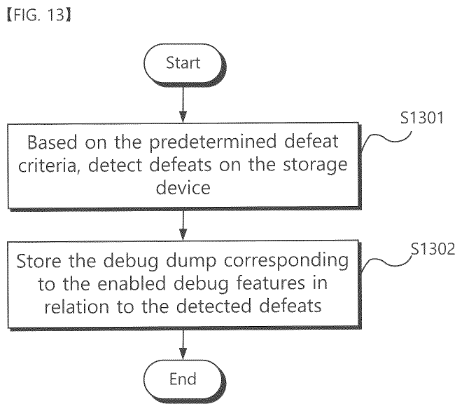

FIG. 13 is a flowchart illustrating an operation of storing a debug dump, corresponding to enabled debug features, when a failure occurs in a storage device.

In operation S1301, the controller 112 detects that a failure has occurred in the storage device 110, based on predetermined failure criteria.

In these cases, the failure criteria may include at least one situation in which the storage device 110 operates abnormally. Accordingly, the controller 112 may recognize that a failure has occurred in the storage device 110, when a situation included in the failure criteria occurs.

For example, when a connection between the storage device 110 and the host 120 is down (for example, link down), the controller 112 may identify that a failure has occurred in the storage device 110. However, the failure criteria and situations included in the failure criteria are not limited to the above examples.

In operation S1302, when it is determined that a failure has occurred in the storage device 110, the controller 112 stores a debug dump, corresponding to the previously enabled debug features, using, e.g., the debug module 1130.

In these cases, the debug dump may be understood as a set of debug logs accumulated and stored in time series until a failure occurs or a set of debug logs stored separately at each time point.

The debug log may include a data log transmitted and received to and from the host 120 by the storage device 110.

According to at least one embodiment, the controller 112 may control the debug module 1130 to store the debug dump based on a predetermined storage criterion even when a failure does not occur.

For example, the controller 112 may control the debug module 1130 to store a debug dump based on data or variance data on some attributes of the risk data.

In at least one example embodiment, the controller 112 controls the debug module 1130 to store a debug dump associated with the corresponding attribute when variance data generated from data of a specific attribute, among the risk data, exceeds a predetermined storage criterion.

In addition, in at least one embodiment, the controller 112 controls the debug module 1130 to store a debug dump associated with a corresponding attribute when an anomaly score obtained by inputting variance data of a specific attribute to the machine learning model exceeds a storage criterion. In these cases, the storage criterion may be a criterion allowing the controller 112 to store the debug dump even before a failure occurs, and may be set to be higher or lower than the second criterion or the third criterion.

In FIGS. 11 and 12, the debug dump has been described as being stored in the nonvolatile memory 111. However, this is merely an example, and example embodiments are not limited thereto. For example, the debug dump may be accumulated and stored in the memory 1113 of the controller 112. In these cases, the debug dump stored in the memory 1113 may be flushed to the nonvolatile memory 111 according to a predetermined period; and/or the controller 112 may further include a main memory implemented as a nonvolatile memory, and the debug dump may be stored in the nonvolatile memory in the controller 112.

Also, the debug dump may be stored in the nonvolatile memory 111 or the memory 1113 based on each debug feature. For example, the debug module 1130 may store each debug log, included in the debug dump, in the memory 1113 or the nonvolatile memory 111 based on corresponding debug features of each debug log.

The storage device 110 according to at least one example embodiment may store a debug dump, associated with an anomaly or a failure occurring in the storage device 110, in real time. Thus, the storage device 110 may secure state-of-the-art data available in failure analysis and quality improvement of the storage device.

For example, the storage device 110 according to the present disclosure may secure accuracy and timeliness of data available in failure analysis and quality improvement for individual attributes.

In addition, when a failure occurs in the storage device 110, the host 120 according to at least one example embodiment may transmit a signal requesting a stored debug dump at the time of occurrence of a failure. The stored debug dump may be provided to the host 120 in response to a request of the host 120. The debug dump, provided to the host 120, may be available in failure analysis and quality improvement. For example, the debug dump may be applied to update the training of the machine learning model 1111.

For example, when a connection between the storage device 110 and the host 120 is down, the storage device 110 may provide the stored debug dump to the host 120 in response to the request of the host 120 through an additional channel to analyze a failure.

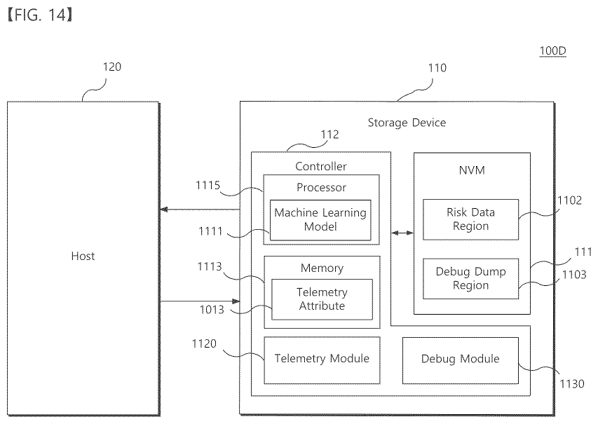

FIG. 14 is a diagram illustrating a storage system 100D further including a telemetry module and a debug module according to at least one example embodiment.

Referring to FIG. 14, the controller 112 according to at least one example embodiment may include a telemetry module 1120, configured to store identified risk data, and a debug module 1130, configured to store a debug dump. As compared to the storage systems 100B and 100C of FIGS. 8 and 11, the same reference numerals denote the same or substantially similar elements as described above, and redundant descriptions will be omitted.

The controller 112 is configured to identify at least a portion of telemetry information 1013, stored in the memory 1113, as risk data. Furthermore, the telemetry module 1120 is configured to store the identified risk data in a nonvolatile memory 111 (for example, a risk data area 1102).

According to at least one example embodiment, the controller 112 is configured to detect an anomaly, in which a failure is likely to occur in the storage device 110, using a machine learning model 1111.

When an anomaly is detected, the controller 112 is configured transmit an alert, associated with the detected anomaly, to the host 120. Also, the controller 112 may enable debug features associated with the detected anomaly.

The controller 112 may receive feedback, corresponding to a transmitted alert, from the host 120. Furthermore, the controller 112 is configured to control an operation of the storage device 110 based on the received feedback.

In these cases, the alert transmitted to the host 120 may include at least a portion of a causal factor inferred for the detected anomaly, an anomaly-detected attribute, and data. The feedback received from the host 120 may include a control signal for the storage device 110.

However, the types and contents of data included in the alert transmitted to the host 120 and the feedback received from the host 120 are not limited to the above examples, and may be referred to as various types of data transmitted and received through bidirectional communication between the storage device 110 and the host 120.

The debug module 1130 is configured to store a debug dump, corresponding to previously enabled debug features, in the nonvolatile memory 111 (for example, a debug dump area 1103) in response to the fact that the processor detects that a failure has occurred in the storage device 110.

As described above, the storage device 110 according to at least one example embodiment may detect an anomaly, in which a failure is likely to occur, using the machine learning model 1111. Furthermore, the storage device 110 may transmit an alert, associated with the detected anomaly, to the host 120. Thus, the storage device 110 may take a preemptive measure before a failure occurs.

Also, the storage device 110 according to at least one example embodiment may enable debug features associated with an attribute in which an anomaly is detected. Furthermore, the debug module 1130 may store a debug dump corresponding to the enabled debug features when a failure occurs. Thus, the storage device 110 according to the present disclosure may secure latest debug data corresponding to each attribute.

Also, the storage device 110 according to at least one example embodiment may select risk data for training of the machine learning model 1111 from the stored telemetry information 1013 based on a predetermined criterion. Thus, the storage device 110 may reduce resources required to train the machine learning model 1111. Furthermore, the storage device 110 may reduce an area required to implement the storage device 110.

As set forth above, a storage device according to example embodiments may predict occurrence of a failure using a machine learning model, and may take a preemptive measure before the occurrence of the failure.

While example embodiments have been shown and described above, it will be apparent to those skilled in the art that modifications and variations could be made without departing from the scope of the present inventive concept as defined by the appended claims.

What is claimed is:

1. A failure prediction method of predicting a failure of a storage device, the failure prediction method comprising:
identifying risk data from at least a portion of telemetry information, stored in a memory, based on a first criterion;
inputting first data of a first attribute, from among the risk data, to a machine learning model;
obtaining a first anomaly score output from the machine learning model;
detecting whether an anomaly is present in the first attribute, based on a determination of whether the first anomaly score satisfies a second criterion;
transmitting an alert, associated with the first attribute, to a host in response to the anomaly being detected; and
controlling an operation of the storage device in response to receiving feedback, corresponding to the alert, from the host,
wherein the machine learning model is configured to be trained on the risk data, to learn a pattern of data from the risk data, and to output anomaly scores based on the learned pattern of the data.

2. The failure prediction method of claim 1, further comprising:
generating first variance data from the first data of the first attribute;
inputting the first variance data to the machine learning model; and
obtaining a second anomaly score from the machine learning model based on the first variance data; and
determining whether an anomaly has occurred in the first attribute, in response to the second anomaly score satisfying a third criterion.

3. The failure prediction method of claim 1, further comprising:
monitoring the telemetry information during a first period to identify the at least the portion of the telemetry information as the risk data; and
storing the identified risk data in at least one of a nonvolatile memory or the memory.

4. The failure prediction method of claim 2, wherein
the machine learning model is trained to output criteria modulated for at least one of the first criterion, the second criterion, and the third criterion, based on at least one of the risk data or the feedback received from the host, and
the failure prediction method further comprises at least one of identifying the risk data or determining whether an anomaly has occurred in the risk data, based on the modulated criteria.

5. The failure prediction method of claim 1, further comprising:
enabling a debug feature, associated with the first attribute, in response to detecting the anomaly in the first attribute;
determining whether a failure in the storage device has occurred, based on a failure criterion; and
storing a debug dump, corresponding to the enabled debug feature in response to a determination that the failure has occurred in the storage device.

6. The failure prediction method of claim 5, further comprising:
transmitting the stored debug dump to the host in response to receiving an information request for the debug dump from the host.

7. The failure prediction method of claim 5, wherein
the feedback comprises a control signal enabling the storage device to prevent the failure from occurring, and
the failure predicting method further comprises controlling an operation of the storage device based on the control signal.

8. A storage device comprising:
a nonvolatile memory; and
a controller comprising a memory configured to store telemetry information on the storage device, the controller including processing circuitry configured to
identify risk data from at least a portion of telemetry information, stored in at least one of the memory or the nonvolatile memory, based on a first criterion;
input first data of a first attribute, from among the risk data, to a machine learning model;
obtain a first anomaly score output from the machine learning model;
detect whether an anomaly is present in the first attribute, based on a determination of whether the first anomaly score satisfies a second criterion;
transmit an alert, associated with the first attribute, to a host in response to the anomaly being detected; and
control an operation of the storage device in response to receiving feedback, corresponding to the alert, from the host,
wherein the machine learning model is configured to be trained on the risk data, to learn a pattern of data from the risk data, and to output anomaly scores based on the learned pattern of the data.

9. The storage device of claim 8, wherein the controller is configured to:
generate first variance data from the first data of the first attribute,
input the first variance data to the machine learning model,
obtain a second anomaly score from the machine learning model based on the first variance data, and
determine whether an anomaly has occurred in the first attribute, in response to the second anomaly score satisfying a third criterion.

10. The storage device of claim 8, wherein
the controller is configured to infer a causal factor of the anomaly in response to the detection of the anomaly, and
the alert transmitted to the host comprises the inferred causal factor.

11. The storage device of claim 8, wherein
the controller is configured to monitor the telemetry information during a first period to identify the at least a portion of the telemetry information as the risk data, and
the processing circuitry is further configured to store the risk data in at least one of the nonvolatile memory or the memory.

12. The storage device of claim 9, wherein
the machine learning model is trained to output criteria, modulated for at least one of the first criterion, the second criterion, and the third criterion, based on at least one of the risk data or the feedback received from the host, and
the controller is further configured to perform at least one of identifying the risk data or determining whether an anomaly occurs in the risk data, based on the modulated criteria.

13. The storage device of claim 8, wherein
the controller is configured to enable a debug feature, associated with the first attribute, in response to detecting the anomaly in the first attribute, and
the processing circuitry is configured to store a debug dump, corresponding to the enabled debug feature, in at least one of the nonvolatile memory or the memory in response to a determination that a failure has occurred in the storage device.

14. The storage device of claim 8, wherein
the feedback comprises a control signal enabling the storage device to prevent the failure, and
the processing circuitry is further configured to control an operation of the storage device based on the control signal.

15. A storage device comprising:
a nonvolatile memory; and
a controller comprising
a memory configured to store telemetry information on the storage device, and
processing circuitry configured to
store risk data identified from the telemetry information,
store a debug dump based on detection of an anomaly, and
identify risk data from at least a portion of telemetry information, stored in the memory, based on a first criterion,
detect whether an anomaly is present in at least a portion of attributes, among the stored risk data, through a machine learning model trained using the identified risk data,
transmit an alert, associated with an attribute in which the anomaly is detected, to a host in response to an anomaly being detected, and
control an operation of the storage device in response to receiving feedback, corresponding to the alert, from the host,
wherein the machine learning model is configured to learn a pattern from received data and to output anomaly scores based on the learned pattern.

16. The storage device of claim 15, wherein the processing circuitry is configured to enable a debug feature, associated with an attribute in which the anomaly is detected in response to the detection of the anomaly in at least a portion of attributes.

17. The storage device of claim 16, wherein the nonvolatile memory comprises a risk data area, in which the risk data is stored, and a debug dump area in which the debug dump corresponding to the enabled debug feature is stored.

18. The storage device of claim 17, wherein the processing circuitry is configured to store the risk data in the risk data area of the nonvolatile memory based on a period associated with the risk data.

19. The storage device of claim 17, wherein the processing circuitry is configured to store the debug dump in the debug dump area of the nonvolatile memory in response to a failure occurring in the storage device.

20. The storage device of claim 15, wherein the processing circuitry is configured to
generate first variance data from first data of a first attribute, among the attributes of the risk data,
input the first variance data to the machine learning model,
obtain a first anomaly score from the machine learning model; and
determine that the anomaly has occurred in the first attribute, in response at least one of the first data satisfying a second criterion or the first anomaly score satisfying a third criterion.
